(19) United States
(12) Patent Application Publication
(10) Pub. No.: US 2007/0148928 A1
(43) Pub. Date: Jun. 28, 2007

(54) Apparatus and Method for Manufacturing Semiconductor Device

(76) Inventor: In Su Kim, Suwon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/615,112

(22) Filed: Dec. 22, 2006

(30) Foreign Application Priority Data
Dec. 28, 2005 (KR) 10-2005-0132297

(51) Int. Cl. H01L 21/425

(52) U.S. Cl. 438/514

(57) ABSTRACT

Disclosed is an apparatus for manufacturing a semiconductor device. The apparatus includes a chamber in which a process is performed, a plasma supply supplying plasma above the chamber, a plate for placing a processing target at a lower portion of the chamber, and an ion capturer capturing ions introduced from the plasma supply below the plasma supply.

### RELATED APPLICATION(S)

This application claims priority under 35 U.S.C. §119(e) of Korean Patent Application No. 10-2005-0132297 filed Dec. 28, 2005, which is incorporated herein by reference in its entirety.

### FIELD OF THE INVENTION

The present invention relates to an apparatus for manufacturing a semiconductor device.

### BACKGROUND OF THE INVENTION

In the process of manufacturing a semiconductor device, the process of forming a gate line is an important process of determining characteristics of the semiconductor device. In the conventional process of manufacturing a semiconductor device, a substrate on which a semiconductor device is formed is adversely influenced by ions generated during an etching reaction. This effect to the substrate exerts an influence on the characteristics of the semiconductor device. In particular, in the case of the semiconductor device such as a complementary metal oxide semiconductor (CMOS) image sensor, the semiconductor device undergoes a strong influence on its characteristics due to the damage during the etching reaction.

Further, in the process of manufacturing a semiconductor device, processes of coating and etching a photoresist are performed to form lines and holes. A process of removing the photoresist left behind after the etch is called an ashing process.

In the conventional method for manufacturing a semiconductor device, the ashing is performed at a high temperature, and then a subsequent (wet) cleaning process is carried out, such that the influence of particles generated in the ashing process is insignificant.

However, in the case of employing a low dielectric constant (low-k) material, a low-temperature ashing process is performed, and various restrictions are imposed on the application of the subsequent cleaning process. Hence, the particles generated in the ashing process must be minimized. Particularly, because the wet cleaning process does not follow the ashing process of a via, the via ashing process is very susceptible to the particles.

### BRIEF SUMMARY

Accordingly, embodiments of the present invention are directed to an apparatus and method for manufacturing a semiconductor device, capable of preventing or minimizing the damage caused by ions and the influence caused by particles in etching and ashing processes, and thereby improving characteristics of the semiconductor device.

According to an aspect of the present invention, an apparatus for manufacturing a semiconductor device, includes a chamber in which a process is performed, a plasma supply supplying plasma above the chamber, a plate placing a processing target at a lower portion of the chamber, and an ion capturer for capturing ions introduced from the plasma supply before the ions enter the chamber below the plasma supply.

In a specific embodiment, the ion capturer may be formed of a conductor.

Further, the ion capturer may include a first ion capturer of a conductor and a second ion capturer of a non-conductor.

According to another aspect of the present invention, a method for manufacturing a semiconductor device comprises: placing an etching target in a chamber; supplying plasma, from which ions are captured by an ion capturer, to the etching target; and etching the etching target.

In a specific embodiment, the ion capturer may be formed of a conductor.

According to yet another aspect of the present invention, a method for manufacturing a semiconductor device includes the steps of: placing an ashing target in a chamber; supplying plasma, from which ions are captured by an ion capturer, to the ashing target; and ashing the ashing target.

In a specific embodiment, the ion capturer may include a first ion capturer of a conductor and a second ion capturer of a non-conductor.

With this construction, the apparatus and method for manufacturing a semiconductor device are capable of preventing the damage caused by ions and the influence caused by particles in etching and ashing processes, and thereby improving characteristics of the semiconductor device.

### BRIEF DESCRIPTION OF THE DRAWINGS

FIG. 1 schematically illustrates an apparatus for manufacturing a semiconductor device in accordance with an embodiment of the present invention.

FIGS. 2A and 2B illustrate an ion capturer for an apparatus for manufacturing a semiconductor device in accordance with a first embodiment of the present invention.

FIGS. 2A and 2B illustrate an ion capturer for an apparatus for manufacturing a semiconductor device in accordance with a second embodiment of the present invention.

### DETAILED DESCRIPTION OF THE PREFERRED EMBODIMENTS

Hereinafter, an apparatus and method for manufacturing a semiconductor device in accordance with an embodiment of the present invention will be described with reference to the accompanying drawings.

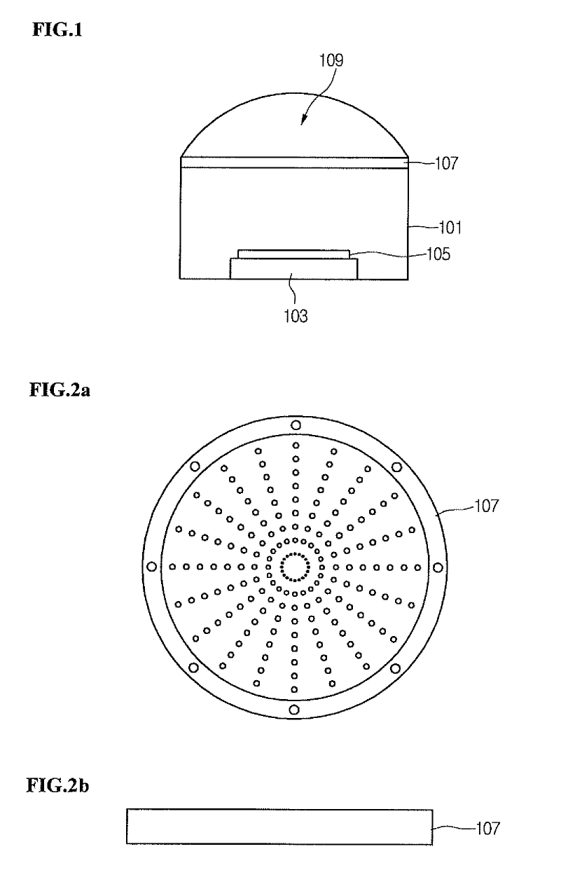

FIG. 1 schematically illustrates an apparatus for manufacturing a semiconductor device in accordance with an embodiment of the present invention.

As illustrated in FIG. 1, the apparatus for manufacturing a semiconductor device can include a chamber 101, a plate 103, an ion capturer 107, and a plasma supply 109.

The chamber 101 can be a space where an etching process or an ashing process is performed.

The plasma supply 109 serves to supply plasma to the chamber 101. The plasma supply 109 can supply the plasma for an etching process when the etching process is performed in the chamber 101. In addition, the plasma supply 109 can supply the plasma for an ashing process when the ashing process is performed in the chamber 101. In addition, the plasma supply 109 can produce and supply the plasma for itself, or receive and supply the plasma produced from the outside (i.e. remote plasma). The plasma supply 109 can be located at a top portion or above the chamber.

The plate 103 call be located on a lower portion of the chamber 101. A substrate 105, for instance a semiconductor substrate, can be placed on the plate 103. The substrate 105 can be an etching target when the etching process is performed. The substrate 105 can be an ashing target when the ashing process is performed.

The ion capturer 107 serves to capture ions introduced from the plasma supply 109 below the plasma supply 109.

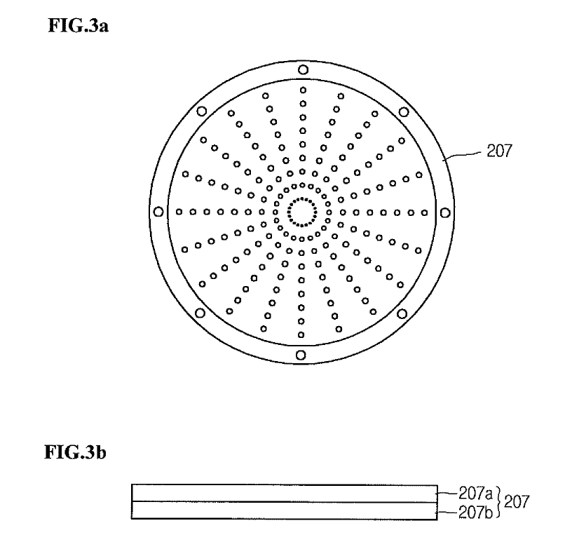

The ion capturer 107 can have a structure as illustrated in FIGS. 2A and 2B. FIGS. 2A and 2B illustrate an ion capturer for an apparatus for manufacturing a semiconductor device in accordance with a first embodiment of the present invention.

The ion capturer 107 can be formed of a conductor. The ion capturer 107 can be formed to have a size of 1 mm to 5 mm, and its hole size and arrangement can have various modifications. The size of each hole of the ion capturer 107 can be proportional to the damage to the substrate 105, as well as an etch rate of the substrate 105. Therefore, the etch rate and the damage percentage of the substrate 105 can be controlled by adjusting the size of each hole of the ion capturer 107. The etching process can be performed, for instance, under the following conditions: pressure of 3 mT to 10 mT, source power of 500 W to 2000 W, bias power of 50 W to 200 W, chlorine (C1₂) of 30 sccm to 100 sccm, hydrogen bromide (HBr) of 100 sccm to 2000 sccm, oxygen (O₂) of 1 sccm to 20 sccm, and nitrogen (N₂) of 1 sccm to 20 sccm.

Meanwhile, an ion capturer 207 according to a second embodiment of the present invention can incorporate a first ion capturer 207a formed of a conductor and a second ion capturer 207b formed of a non-conductor.

The ion capturer 107 according to a first embodiment of the present invention can be formed of a conductor, such as for example, an aluminum material. However, in the case of capturing ions using the aluminum material, the ions can be captured, but arc and resulting particles can be generated. As described above, in the case of applying the ashing process to the semiconductor device employing the low-k material, the particles must be generated to the minimum extent.

In order to meet this requirement, the ion capturer 207 according to a second embodiment of the present invention includes the first ion capturer 207a of the conductor and the second ion capturer 207b of the non-conductor. FIGS. 3A and 3B illustrate an ion capturer for an apparatus for manufacturing a semiconductor device in accordance with a second embodiment of the present invention.

In this manner, the ion capturer 207 is formed of the conductor and the non-conductor, so that it can capture ions, prevent arc and the resulting particles from being generated. The second ion capturer 207b of the non-conductor can be formed of, for example, aluminum oxide (Al₂O₃).

A process of performing an etching process using the semiconductor device manufacturing apparatus having this construction will be described in brief.

In a method for manufacturing a semiconductor device according to the present invention, first, a substrate 105, which is the etching target, can be placed in the chamber 101. The etching target can be supplied with plasma for the etching. Here, the plasma from which ions are captured by the ion capturer 107 is supplied, thereby etching the etching target.

In this manner, the ions are captured from the plasma by the ion capturer 107, so that the etching target can be prevented from being damaged. In a specific embodiment for an etching process, the ion capturer 107 can be formed of a conductor.

A process of performing an ashing process using the semiconductor device manufacturing apparatus having this construction will be described in brief.

In a method for manufacturing a semiconductor device according to the present invention, first, a substrate 105, which is the ashing target, can be placed in the chamber 101. The etching target is supplied with plasma for the ashing. Here, the plasma from which ions are captured by the ion capturer 207 is supplied, thereby ashing the ashing target.

In this manner, the ions are captured from the plasma by the ion capturer 207, so that the ashing target can be prevented from being damaged as well as the arc and the resulting particles can be prevented from being generated. In a specific embodiment for an ashing process, the ion capturer 207 can be formed of a conductor for the first ion capturer 207a and a non-conductor for the second ion capturer 207b.

As described above, according to embodiments of the present invention, the apparatus and method for manufacturing a semiconductor device can minimize or prevent damage caused by ions and influence caused by particles in the etching and ashing processes, so that they can improve characteristics of the semiconductor device.

I claim:

1. An apparatus for manufacturing a semiconductor device, comprising:
a chamber for performing a process;
a plasma supply for supplying plasma above the chamber;
a plate for placing a processing target at a lower portion of the chamber; and
an ion capturer for capturing ions introduced by the plasma supply below the plasma supply.

2. The apparatus according to claim 1, wherein the ion capturer is formed of a conductor.

3. The apparatus according to claim 1, wherein the ion capturer comprises a first ion capturer formed of a conductor and a second ion capturer formed of a non-conductor.

4. A method for manufacturing a semiconductor device, comprising:
placing an etching target in a chamber;
supplying plasma, from which ions are captured by an ion capturer, to the etching target; and
etching the etching target.

5. The method according to claim 4, wherein the ion capturer is formed of a conductor.

6. A method for manufacturing a semiconductor device, comprising:
placing an ashing target in a chamber;
supplying plasma, from which ions are captured by an ion capturer, to the ashing target; and
ashing the ashing target.

7. The method according to claim 6, wherein the ion capturer comprises a first ion capturer formed of a conductor and a second ion capturer formed of a non-conductor.
